(19) United States
(12) Patent Application Publication
(10) Pub. No.: US 2020/0313018 A1
(43) Pub. Date: Oct. 1, 2020

(54) BACK SHEET FOR SOLAR MODULE AND MANUFACTURING METHOD THEREFOR

(71) Applicant: KOLON INDUSTRIES, INC., Seoul (KR)

(72) Inventor: Dong-Hyeon CHOI, Yongin-si (KR)

(73) Assignee: KOLON INDUSTRIES, INC., Seoul (KR)

(21) Appl. No.: 16/313,677

(22) PCT Filed: Jun. 27, 2017
(86) PCT No.: PCT/KR2017/006760

§ 371 Date: Dec. 27, 2018

(30) Foreign Application Priority Data
Jun. 28, 2016 (KR) 10-2016-0080573
May 16, 2017 (KR) 10-2017-0060454

(51) Int. Cl. H01L 31/056; H01L 31/048

(52) U.S. Cl. CPC H01L 31/056; H01L 31/048

(57) ABSTRACT

Provided are a backsheet for a solar cell module and a manufacturing method thereof. More particularly, the present invention relates to a novel backsheet for a photovoltaic module capable of replacing a structure in which a fluoride film/a polyethylene terephthalate (PET) film/a fluoride film or a white polyester film/a transparent polyester film/a white polyethylene film are stacked according to the related art with a single layer polyester film, and capable of being used in a double-sided light receiving photovoltaic module as well as a general front-sided light receiving photovoltaic module to replace a glass or fluorine-based polymer resin.

### TECHNICAL FIELD

The present invention relates to a backsheet for a solar cell module and a manufacturing method thereof, and more particularly, to a backsheet for a photovoltaic module capable of replacing a structure in which a fluoride film/a polyethylene terephthalate (PET) film/a fluoride film or a white polyester film/a transparent polyester film/a white polyethylene film are stacked according to the related art with a single layer polyester film, and capable of being used in a double-sided light receiving photovoltaic module as well as a general front-sided light receiving photovoltaic module to replace a glass or fluorine-based polymer resin.

### BACKGROUND ART

A solar cell for solar power generation is made of silicon or various compounds and may generate electricity. However, since sufficient output power may not be obtained from a single solar cell, each of the solar cells should be connected in series or in parallel with each other. A state in which the solar cells are connected to each other as describe above is called a “photovoltaic module”.

The solar cell (photovoltaic, PV) module may be configured by stacking glass, a first encapsulant, a solar cell, a second encapsulant, and a backsheet. As the first and second encapsulants, ethylene vinylacetate (EVA), or the like, is used.

A general solar cell module may receive light only through a front surface thereof to generate power, and thus, there is a limitation in increasing efficiency. Therefore, recently, a double-sided light receiving solar cell receiving light through both front and rear surfaces thereof to generate power has been developed, and there is a need to develop a backsheet suitable for this double-sided light receiving solar cell. Since the double-sided light receiving solar cell module should absorb visible light reaching the ground and block ultraviolet light, unlike an opaque white backsheet used in a front-sided light receiving solar cell module according to the related art, the backsheet used in the double-sided light receiving Solar cell module should be transparent, and at the same time, since the backsheet is exposed to UV light, the backsheet should have a UV blocking property in addition to durability and moisture resistance.

### DISCLOSURE

### Technical Problem

An object of the present invention is to provide a backsheet capable of replacing a structure of an existing backsheet in which a transparent film and a white film are stacked with a single layer film according to the present invention, as a core material for protecting a solar cell module. That is, an embodiment of the present invention is directed to providing a backsheet capable of implementing physical properties equivalent or similar to those in a case of using a film having a stacking structure according to the related art, while being composed of a single layer.

Another object of the present invention is to provide a backsheet for a solar cell module capable of being used in a double-sided light receiving photovoltaic module as well as a front-sided light receiving photovoltaic module by including a transparent portion on which a solar cell is positioned, and capable of improving light receiving efficiency of the Solar cell module and preventing aging and degradation of a polyester base film by having excellent visible light transmittance, UV blocking property, and moisture resistance.

Another object of the present invention is to provide a backsheet for a solar cell module capable of having excellent reflectance to improve photovoltaic power generation efficiency without stacking a separate white film by including a printing layer having excellent reflectance.

Another object of the present invention is to provide a backsheet for a Solar cell module capable of improving an adhesion property with an encapsulant.

### Technical Solution

In one general aspect, a backsheet for a solar cell module includes: a polyester base film; and a printing layer formed on only a portion of one surface or both surfaces of the polyester base film, wherein the printing layer contains a white pigment.

In another general aspect, a manufacturing method of a backsheet for a Solar cell module includes: a) preparing a compound chip by kneading a polyester resin having an intrinsic viscosity of 0.8 to 1.0 dl/g and a photostabilizer;

b) manufacturing an un-stretched sheet by adding the compound chip to a polyester resin having an intrinsic viscosity of 0.65 to 0.8 dl/g and melt-extruding the resultant, the compound chip being added in a content range in which the following physical properties are satisfied: average visible light transmittance at a wavelength of 380 to 1000 nm is 85% or more, and average UV light transmittance at a wavelength of 250 to 380 nm is 10% or less;

c) manufacturing a polyester base film by uni-axially stretching the un-stretched sheet in a longitudinal direction and then bi-axially stretching the sheet in a transverse direction; and

d) forming a printing layer by applying a printing layer composition containing a binder resin, an organic solvent, and a white pigment onto only a portion of a surface of a polyester base film, the white pigment being contained in a content range in which the printing layer satisfies the following physical property: average visible light reflectance at a wavelength of 380 to 1000 nm is 85% or more.

### Advantageous Effects

As set forth above, the backsheet for a solar cell module according to the present invention has advantages in that since the backsheet is made of the single layer polyester film, manufacturing cost may be decreased, and since the portion of the backsheet on which the solar cell is positioned is transparent, the backsheet may be applied to both of the front-sided light receiving solar cell module and the double-sided light receiving solar cell module.

In addition, the backsheet may have the UV blocking function and the high reflection function with respect to the energy conversion wavelength, such that the backsheet may have functions of both of the transparent film and the white film according to the related art, thereby making it possible to improve power conversion efficiency of the solar cell module.

Further, in the backsheet for a solar cell module according to the present invention, the printing layer having an excellent adhesion property with the encapsulant and having excellent flexibility is formed, such that durability and workability may be improved, the process may be simplified, and cost may be decreased.

### DESCRIPTION OF THE DRAWINGS

FIG. 1 illustrates an example of a backsheet for a solar cell module according to the present invention.

FIG. 2 illustrates an example of the backsheet for a solar cell module according to the present invention.

FIG. 3 illustrates an example of the backsheet for a solar cell module according to the present invention.

FIG. 4 is a cross-sectional view illustrating an example of the backsheet for a solar cell module according to the present invention.

FIG. 5 is a cross-sectional view illustrating an example of a solar cell module using the backsheet for a solar cell module according to the present invention.

FIG. 6 is a photograph illustrating an example of the backsheet for a solar cell module according to the present invention.

### DETAILED DESCRIPTION OF THE MAIN ELEMENTS

10: Polyester base film

20: Printing layer

100: Backsheet for solar cell module

200: Solar cell

300: Encapsulant

400: Front substrate

500: Ground

### Best Mode

Hereinafter, the present invention will be described in more detail through detailed examples or exemplary embodiments including the accompanying drawings. However, the following detailed examples or exemplary embodiments are only to specifically explain the present invention. Therefore, the present invention is not limited thereto, but may be implemented in various forms.

In addition, unless defined otherwise in the specification, all the technical and scientific terms used in the present specification have the same meanings as those that are generally understood by those who skilled in the art. The terms used in the specification are only to effectively describe a specific exemplary embodiment, but are not to limit the present invention.

In addition, unless the context clearly indicates otherwise, it should be understood that a term in singular form used in the specification and the appended claims includes the term in plural form.

The present inventors studied in order to develop a polyester film for a backsheet for a photovoltaic module having a UV blocking function, a high visible light reflection function, and a single layer structure, and as a result, the present inventors found that it is possible to provide a backsheet for a solar cell module capable of finally having a protection function of the solar cell module and increasing efficiency through light reflection by using a photostabilizer blocking UV light, more specifically, absorbing UV light in a wavelength region of 250 to 380 nm, which is a wavelength region of UV light reaching the ground while directly affecting decomposition of a polymer material, and forming a printing layer containing a white pigment for the reflection function on a portion of one surface or both surfaces thereof using a printing method except for a position of a solar cell receiving light to generate power, thereby completing the present invention.

According to an aspect of the present invention, a backsheet for a solar cell module includes: a polyester base film; and a printing layer formed on only a portion of one surface or both surfaces of the polyester base film, wherein the printing layer contains a white pigment.

According to the aspect of the present invention, average visible light transmittance of the polyester base film at a wavelength of 380 to 1000 nm may be 85% or more, and average UV light transmittance thereof at a wavelength of 250 to 380 nm may be 10% or less.

In addition, average visible light reflectance of the printing layer at a wavelength of 380 to 1000 nm may be 85% or more.

According to the aspect of the present invention, the polyester base film may contain any one or two or more photostabilizers selected from the group consisting of a benzophenone based compound, a benzotriazole based compound, a benzoxazinone based compound, a benzoate based compound, a phenyl salicylate based compound, and a hindered amine based compound.

According to the aspect of the present invention, a content of the photostabilizer may be 0.01 to 5 wt % based on a total weight of the polyester base film.

According to the aspect of the present invention, an intrinsic viscosity of the polyester base film may be 0.65 to 0.8 dl/g, a thermal shrinkage rate ΔHS thereof after standing at 150° C. for 30 minutes may satisfy the following Equation 1, and an elongation retention rate S thereof after standing at 121° C. and RH of 100% for 75 hours may satisfy the following Equation 2.

0≤ΔHS≤2 [Equation 1]

In Equation 1, ΔHS=(HS₂−HS₁)/HS₁×100, wherein ΔHS is the thermal shrinkage rate, HS₂ is a length of a polyester base film in a machine direction, measured after standing at 150° C. for 30 minutes, and HS₁ is a length of the polyester base film in the machine direction before treatment.

60%≤S≤99% [Equation 2]

In Equation 2, S=S₂/S₁×100, wherein S is the elongation retention rate in the machine direction, S₂ is an elongation of the polyester base film in the machine direction, measured after standing at 121° C. and RH of 100% for 75 hours, and S₁ is an elongation thereof in the machine direction (MD) of the polyester base film before treatment.

According to the aspect of the present invention, the polyester base film may have a thickness of 50 to 350 μm, and the printing layer may have a thickness of 1 to 35 μm. According to the aspect of the present invention, the printing layer may contain an acrylic based resin, a polyester based resin or a polyurethane based resin as a binder resin.

According to the aspect of the present invention, the white pigment may be contained in the printing layer in a content of 30 to 50 wt %.

According to the aspect of the present invention, the white pigment may be made of titanium oxide fine particles coated with silica and having an average particle size of 0.15 to 0.25 μm.

According to the aspect of the present invention, the printing layer may be selected from i) printing layers formed only on a portion of a surface of the polyester base film to be disposed apart from each other, ii) a printing layer formed only on a portion of the surface of the polyester base film and having a continuous pattern, iii) a printing layer formed only on a portion of the surface of the polyester base film along an edge of the solar cell, and iv) a printing layer formed only on a portion of the surface of the polyester base film in a sea island form.

According to the aspect of the present invention, the printing layer may partially overlap the solar cell of the solar cell module.

According to the aspect of the present invention, the polyester base film may be composed of a polyester film and a primer coating layer containing any one of a polyurethane based resin and a polyester based resin or a mixture thereof and formed on one surface or both surfaces of the polyester film.

According to an aspect of the present invention, the manufacturing method of a backsheet for a solar cell module includes:

a) preparing a compound chip by kneading a polyester resin having an intrinsic viscosity of 0.8 to 1.0 dl/g and a photostabilizer;

b) manufacturing an un-stretched sheet by adding the compound chip to a polyester resin having an intrinsic viscosity of 0.65 to 0.8 dl/g and melt-extruding the resultant, the compound chip being added in a content range in which the following physical properties are satisfied: average visible light transmittance at a wavelength of 380 to 1000 nm is 85% or more, and average UV light transmittance at a wavelength of 250 to 380 nm is 10% or less;

c) manufacturing a polyester base film by uni-axially stretching the un-stretched sheet in a longitudinal direction and then bi-axially stretching the sheet in a transverse direction; and

d) forming a printing layer by applying a printing layer composition containing a binder resin, an organic solvent, and a white pigment onto only a portion of a surface of a polyester base film, the white pigment being contained in a content range in which the printing layer satisfies the following physical property: average visible light reflectance at a wavelength of 380 to 1000 nm is 85% or more.

In the manufacturing method according to the aspect of the present invention, in step d), an application method may be selected from a screen printing method, an offset method, a digital printing method, a roll coating method, a gravure coating method, a reverse coating method, a spray coating method, and an air knife coating method.

Hereinafter, an example of the backsheet for a solar cell module according to the present invention will be described in detail.

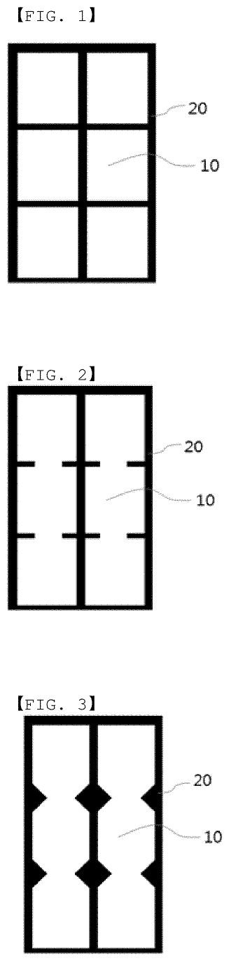

The example of the backsheet for a solar cell module according to the present invention will be described in detail with reference to the accompanying drawings. As illustrated in FIGS. 1 to 4, a printing layer 20 is formed on a polyester base film 10, particularly only a portion of a surface of the polyester base film 10. More specifically, the printing layer may be selected from i) printing layers formed only on a portion of a surface of the polyester base film to be disposed apart from each other, ii) a printing layer formed only on a portion of the surface of the polyester base film and having a continuous pattern, iii) a printing layer formed only on a portion of the surface of the polyester base film along an edge of the solar cell, and iv) a printing layer formed only on a portion of the surface of the polyester base film in a sea island form.

The sea island form may be a form in which a portion on which the printing layer is not formed forms an island portion, a portion on which the printing layer is formed forms a sea portion, and the solar cell of the solar cell module is positioned on some or all parts of the island portion. Further, the sea portion and the solar cell may partially overlap each other. That is, according to the aspect of the present invention, the printing layer may partially overlap the solar cell of the solar cell module. Here, the sea portion and the solar cell partially overlap each other, which means that the solar cell may be deviated from a boundary of the island portion to partially overlap the printing layer on the sea portion.

The island portion and the solar cell may partially overlap each other. Here, the island portion and the solar cell partially overlap each other, which means that an edge of the island portion and the edge of the solar cell are formed at the same position, or the edge of the island portion may be formed to protrude toward the solar cell so as to overlap the solar cell.

More specifically, the printing layer may be formed on some or all parts of portions except for the portion on which the solar cell of the solar cell module is positioned. An interval between solar cells may be shown in white by allowing a size of the island portion to be equal to or smaller than that of the solar cell. More specifically, at the time of assembling the solar cell module, at least one solar cell may be provided on the backsheet, and the printing layer may be partially or entirely formed on a portion corresponding to a circumference of at least one solar cell provided as described above.

In detail, as illustrated in FIG. 1, in a portion on which at least one solar cell is positioned, the printing layer 20 may be formed on a portion corresponding to a circumference of the solar cell. Alternatively, as illustrated in FIGS. 2 and 3, a sea portion and an island portion are not completely distinguished from each other, but the printing layer may be partially discontinuously formed depending on a shape and lay-out of the solar cell.

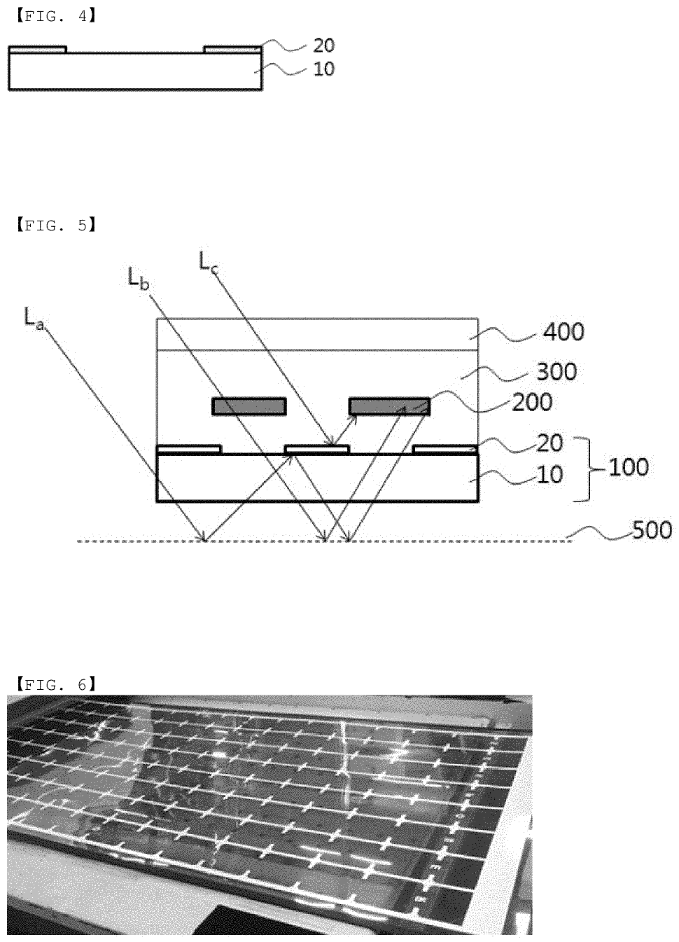

In addition, FIG. 4, which is a cross-sectional view illustrating an example of the backsheet according to the present invention, illustrates that the printing layer 20 is formed on one surface of the polyester base film 10. At the time of applying the backsheet according to the present invention to a solar cell module, a solar cell 200 may be positioned on a transparent portion of the polyester base film 10 on which the printing layer 20 is not formed, and if necessary, the printing layer and the solar cell may partially overlap each other.

FIG. 5, which is a cross-sectional view illustrating an example of a solar cell module using the backsheet for a solar cell module according to the present invention, illustrates transmission and reflection of visible light.

FIG. 6, which is a photograph illustrating an example of a printing pattern in a case of applying the backsheet illustrated in FIG. 2, illustrates an entire printing pattern.

FIGS. 1 to 6 are only to assist in the understanding of the present invention, but the present invention is not limited thereto. That is, a shape of the printing layer may be changed depending on a structure or shape of the solar cell, and the printing layer may be formed on one surface or both surfaces of the polyester base film.

[Polyester Base Film]

According to the aspect of the present invention, the present inventors studied in order to block UV light in a wavelength region of 250 to 380 nm, which is a wavelength region of UV light reaching the ground, to prevent aging and degradation of the polyester base film, and as a result, it was appreciated that the polyester base film may be applied to a double-sided light receiving photovoltaic module as well as a front-sided light receiving photovoltaic module by containing a polyester resin and a photostabilizer. The photostabilizer may include any one or two or more selected from the group consisting of a benzophenone based compound, a benzotriazole based compound, a benzoxazinone based compound, a benzoate based compound, a phenyl salicylate based compound, and a hindered amine based compound, but is not limited thereto.

It is preferable that the photostabilizer is used in a content range in which the photostabilizer may block UV light in a wavelength region of 250 nm to 380 nm, which is the wavelength region of UV light, to implement the following physical properties: UV light transmittance of 10% or less, more preferably, 5% or less. Although not limited, but the photostabilizer may be used in a content of 0.01 to 5 wt % based on a total weight of the polyester base film. More preferably, the photostabilizer may be used in a content of 0.1 to 1.0 wt %.

In a range in which UV light transmittance of 10% or less, more specifically, 0.1 to 10%, and more preferably, 0.1 to 5%, the aging of the polyester base film may be prevented, and durability and weather resistance may be excellent.

It is preferable to add the photostabilizer at the time of preparing the polyester base film, and more preferably, dispersibility of the photostabilizer may be further improved by preparing a compound chip containing the photostabilizer, mixing the compound chip with a polyester chip, and melt-extruding the mixture to manufacture a film.

As the polyester resin, any polyester resin may be used without limitation as long as it is generally used to manufacture a polyester film. More specifically, for example, polyethylene terephthalate, polyethylene naphthalate, polybutylene naphthalate, and the like, may be used, but the polyester resin is not limited thereto.

The polyester resin is a general term indicating polymers in which a covalent bond between monomer residues, which is a main bond of a main chain, is an ester bond, and the polyester resin may be generally obtained by condensation-polymerization of a dicarboxylic acid compound and a dihydroxy compound, or dicarboxylic acid ester derivative and a dihydroxy compound.

Here, examples of the dicarboxylic acid compound may include aromatic dicarboxylic acids such as terephthalic acid, 2,6-naphthalene dicarboxylic acid, isophthalic acid, diphenyl dicarboxylic acid, diphenyl sulfone dicarboxylic acid, diphenoxyethane dicarboxylic acid, 5-sodium sulfoisophthalic acid, and phthalic acid; aliphatic dicarboxylic acids such as oxalic acid, succinic acid, adipic acid, sebacic acid, dimer acid, maleic acid, and fumaric acid; alicyclic dicarboxylic acids such as cyclohexane dicarboxylic acid; oxycarboxylic acids such as paraoxybenzoic acid; and the like. Further, examples of the dicarboxylic acid ester derivative may include esterified compounds of the dicarboxylic acid compounds, for example, dimethyl terephthalate, diethyl terephthalate, terephthalic acid-2-hydroxyethyl methyl ester, dimethyl 2,6-naphthalenedicarboxylate, dimethyl isophthalate, dimethyl adipate, dimethyl maleate, dimethyl dimerate, and the like. Further, one of them may be used alone, or a mixture thereof two or more thereof may be used.

Examples of the dihydroxy compound may include aliphatic dihydroxy compounds such as ethylene glycol, 1,2-propanediol, 1,3-propanediol, 1,3-butanediol, 1,4-butanediol, 1,5-pentanediol, 1,6-hexanediol, neopentyl glycol; polyoxyalkylene glycols such as diethylene glycol, polyethylene glycol, polypropylene glycol, polytetramethylene glycol; alicyclic dihydroxy compounds such as 1,4-cyclohexane dimethanol; aromatic dihydroxy compounds such as bisphenol A, bisphenol S; and the like. Further, one of them may be used alone, or a mixture thereof two or more thereof may be used.

Among them, terephthalic acid, 2,6-naphthalene dicarboxylic acid, isophthalic acid, or the like, may be preferably used as the dicarboxylic acid compound, and neopentyl glycol, ethylene glycol, 1,3-propanediol, 1,4-butanediol, polytetramethylene glycol, 1,4-cyclohexane dimethanol, or the like, may be preferably used as the dihydroxy compound.

Among them, it is preferable to use polyethylene terephthalate (PET) composed of terephthalic acid or dimethyl terephthalate and ethylene glycol.

Further, average visible light transmittance of the polyester base film at a wavelength of 380 to 1000 nm is 85% or more, visible light transmittance thereof at a wavelength of 550 nm is 85% or more, and average UV light transmittance thereof at a wavelength of 250 to 380 nm is 10% or less, which is preferable in that photovoltaic power generation efficiency may be improved at the time of applying the polyester base film to the double-sided light receiving solar cell module.

In addition, as the polyester base film, a polyester film having excellent hydrolysis resistance may be used, and a film having excellent hydrolysis resistance may be manufactured and used, or a commercialized product may be used. As an example, as the polyester film having excellent hydrolysis resistance, a polyester film in which a content of an oligomer generated at the time of condensation polymerization is low may be used. Further, hydrolysis resistance may be further improved by additionally performing thermal treatment for improving hydrolysis resistance known in the art on the polyester film to decrease a content of water in the polyester film and decreasing a shrinkage rate thereof.

More preferably, the polyester resin used at the time of preparing the compound chip of the polyester resin and the photostabilizer has an intrinsic viscosity of 0.80 to 1.0 dl/g, and it is preferable that the polyester resin used together with the compound chip at the time of manufacturing the polyester base film has an intrinsic viscosity of 0.6 to 0.80 dl/g. When the intrinsic viscosity of the polyester resin used at the time of preparing the compound chip is less than 0.80 dl/g, a viscosity of the compound chip may be decreased, and thus processability and durability may be deteriorated at the time of manufacturing a film, and when the intrinsic viscosity of the polyester resin at the time of manufacturing the polyester base film is less than 0.6 dl/g, at the time of processing, shearing stress may be decreased due to a low intrinsic viscosity, and thus, a viscosity of the polyester base film may be decreased, processability may be improved, but it is impossible to expect improvement of durability and weather resistance. In addition, when the intrinsic viscosity of the polyester resin at the time of manufacturing the polyester base film is more than 0.80 dl/g, at the time of manufacturing the polyester base film using existing equipment for producing a polyethylene terephthalate resin, productivity may be deteriorated due to a high discharge pressure and breakage occurring at the time of stretching.

It is preferable that a finally manufactured film has an intrinsic viscosity of 0.65 to 0.8 dl/g. Since durability and weather resistance are excellent when the intrinsic viscosity is within the above-mentioned range, at the time of applying the polyester base film to the double-sided light receiving solar cell module, it is impossible to use the polyester base film for a long period of time.

In addition, if necessary, the polyester base film may further contain inorganic particles in order to improve a film forming property of the film. Here, examples of the inorganic particles may include silica particles, barium sulfate particles, alumina particles, and the like, but are not limited thereto.

Further, the polyester base film may have a thickness of 50 to 350 μm, which is preferable in that the polyester base film is suitable for being used in the backsheet for the solar cell module, but the thickness of the polyester base film is not limited thereto.

In addition, a thermal shrinkage rate ΔHS of the polyester base film according to the present invention after standing at 150r for 30 minutes may satisfy the following Equation 1, and an elongation retention rate S thereof after standing at 121° C. and RH of 100% for 75 hours may satisfy the following Equation 2.

0≤ΔHS≤2 [Equation 1]

In Equation 1, ΔHS=(HS₂−HS₁)/HS₁×100, wherein ΔHS is the thermal shrinkage rate, HS₂ is a length of a polyester base film in a machine direction, measured after standing at 150° C. for 30 minutes, and HS₁ is a length of the polyester base film in the machine direction before treatment.

60%≤S≤99% [Equation 2]

In Equation 2, S=S₂/S₁×100, wherein S is the elongation retention rate in the machine direction, S₂ is an elongation of the film in the machine direction, measured after standing at 121° C. and RH of 100% for 75 hours, and S₁ is an elongation thereof in the machine direction (MD) before treatment.

It is preferable that the thermal shrinkage rate in the machine direction is 2.0% or less, preferably, 0.5 to 1.5%, and more preferably, 0.5 to 1.0%. In the case in which the thermal shrinkage rate is more than 2.0%, thermal resistance may be deteriorated, such that physical properties may be significantly changed by heat.

Further, it is preferable that after standing at 121° C. and RH of 100% for 75 hours, the elongation retention rate in the machine direction may be 60 to 99%, preferably, 70 to 99%. In the case in which the elongation retention rate is less than 60%, as time goes by, rapid deterioration of physical properties may occur, such that long-term durability may be deteriorated.

According to the present invention, weather resistance may be significantly improved by using the polyester base film simultaneously satisfying the above-mentioned intrinsic viscosity, thermal shrinkage rate, and elongation retention rate as the polyester base film, such that at the time of applying the polyester film to the backsheet for a solar cell module, weather resistance may be improved by 10% or more as compared to a case of using a general polyester film. [Printing Layer]

According to the aspect of the present invention, since the printing layer containing the white pigment may perform functions of a white film according to the related art due to a high reflection function with respect to an energy conversion wavelength, the backsheet for a solar cell module according to the present invention may perform functions of both a transparent film and a white film according to the related art while being used alone without stacking a separate white film thereon, such that efficiency of the solar cell module may be improved, a process may be simplified, and cost may be decreased.

According to the aspect of the present invention, the printing layer containing the white pigment is a layer reflecting light in a wavelength region in which the light transmits through a solar cell, for example, light in ultraviolet (UV) and near infrared (IR) regions. It is preferable that the average visible light reflectance of the printing layer at a wavelength of 380 to 1000 nm is 85% or more, and visible light reflectance thereof at a wavelength of 550 nm is 85% or more. Within the above-mentioned range, energy efficiency may be increased by reflecting the energy conversion wavelength into the solar cell module. That is, efficiency of the solar cell may be further increased by allowing the light reflected on the printing layer to be reflected again in the front substrate of the solar cell module to thereby be incident on the solar cell.

According to the aspect of the present invention, the printing layer containing the white pigment may be formed by applying a white ink composition containing a binder resin, an organic solvent, and the white pigment. Here, as an application method, a screen printing method, an offset method, a digital printing method, a roll coating method, a gravure coating method, a reverse coating method, a spray coating method, an air knife coating method, or the like, may be used, but the application method is not limited thereto.

In order to increase a content of the white pigment for further improving reflectance, as the binder resin, a binder resin having an excellent close adhesion property with the polyester base film may be preferably used. Further, in view that a difference in reflective index between the binder resin and the polyester resin is small and thus excellent transparency may be implemented, it is preferable to use an acrylic based resin, a polyester based resin, a polyurethane based resin, or the like. More preferably, the acrylic based resin may be used in view of excellent durability and adhesion property.

As the white pigment, for example, titanium oxide, zinc oxide, antimony oxide, calcium carbonate, or the like, may be used. In view of increasing reflectance, it is preferable to use titanium oxide, and in view of further improving dispersibility with respect to the binder resin, a close adhesion property with the polyester base film, and a reflection property, titanium oxide fine particles coated with silica may be used.

Reflectance with respect to visible light having a wavelength of 380 to 1000 nm may be implemented to be 85% or more by using titanium oxide fine particles coated with silica, and it is possible to form the printing layer in which excitation by UV light is almost suppressed may be suppressed, and of which durability is improved. Further, the printing layer serves to improve light efficiency by reflecting light passing through the solar cell to return the light to the solar cell, and serves to suppress photolysis of PET by blocking UV light transmitted through the PET film configuring the backsheet. The white pigment may have an average particle size of 0.15 to 0.25 μm, but is not limited thereto.

It is preferable that the white pigment is used in a content range in which the following physical properties may be satisfied: average visible light reflectance at a wavelength of 380 to 1000 nm is 85% or more and visible light reflectance at a wavelength of 550 nm is 85% or more. More specifically, the white pigment may be contained in the printing layer in a content range of 30 to 50 wt %, but is not limited thereto.

As the organic solvent, any organic solvent may be used as long as it may dissolve the binder resin. As a specific example, one or a mixture of two or more of solvent naphtha, dimethylformamide, methyl ethyl ketone, acetone, ethyl acetate, tetrahydrofuran, dioxane, cyclohexanone, n-hexane, toluene, xylene, methanol, ethanol, n-propanol, isopropanol, and the like, may be used, but the organic solvent is not limited thereto.

Further, if necessary, the white ink composition may further contain a dispersant for improving dispersibility of the white pigment.

According to the aspect of the present invention, the printing layer has a thickness of 1 to 35 μm, which is preferable in that a step between the polyester base film and the printing layer is small and the printing layer contains a sufficient content of the white pigment, but the printing layer is not limited thereto.

According to the aspect of the present invention, the polyester base film having excellent visible light transmittance is used, such that light receiving efficiency may be further improved by returning visible light reached the ground 500 such as Lₐ and L_{b} to the solar cell 200 of the solar cell module as illustrated in FIG. 5. Further, light receiving efficiency may be further improved by returning light received from the front substrate 400 to transmit through the front substrate such as L_{c} to the solar cell 200 from the printing layer 20.

Therefore, the backsheet for a solar cell module according to the present invention may be applied to the double-sided light receiving solar cell module, at the time of applying the backsheet for a solar cell module according to the present invention to the double-sided light receiving solar cell module, light receiving efficiency may be further improved.

[Manufacturing Method]

As a specific example, a manufacturing method of a backsheet for a solar cell module according to the present invention may include: a) preparing a compound chip by kneading a polyester resin having an intrinsic viscosity of 0.8 to 1.0 dl/g and a photostabilizer;

b) manufacturing an un-stretched sheet by adding the compound chip to a polyester resin having an intrinsic viscosity of 0.65 to 0.8 dl/g and melt-extruding the resultant, the compound chip being added in a content range in which the following physical properties are satisfied: average visible light transmittance at a wavelength of 380 to 1000 nm is 85% or more, and average UV light transmittance at a wavelength of 250 to 380 nm is 10% or less;

c) manufacturing a polyester base film by uni-axially stretching the un-stretched sheet in a longitudinal direction and then bi-axially stretching the sheet in a transverse direction; and

d) forming a printing layer by applying a printing layer composition containing a binder resin, an organic solvent, and a white pigment onto only a portion of a surface of a polyester base film, the white pigment being contained in a content range in which the printing layer satisfies the following physical property: average visible light reflectance at a wavelength of 380 to 1000 nm is 85% or more.

The photostabilizer may be uniformly dispersed in the film by compounding the polyester resin and the photostabilizer in advance as in step a) to manufacture the film, thereby making it possible to further improve film-forming stability of the film. In this case, it is preferable to use the polyester resin having an intrinsic viscosity of 0.8 to 1.0 dl/g. Within the above-mentioned range, durability may be further improved. Here, a content of the photostabilizer in the compound chip may be 5 to 30 wt %, which is preferable in that dispersibility is improved within the above-mentioned range, but the content of the photostabilizer is not limited thereto.

Step b) is a process of mixing the compound chip prepared in step a) and the polyester resin having an intrinsic viscosity of 0.65 to 0.8 dl/g with each other to manufacture the film. Here, it is preferable that the compound chip is used in a content range in which the following physical properties are satisfied: average visible light transmittance at a wavelength of 380 to 1000 nm is 85% or more, visible light transmittance at a wavelength of 550 nm is 85% or more, and average UV light transmittance at a wavelength of 250 to 380 nm is 10% or less. More specifically, the photostabilizer may be used in a content range of 0.01 to 5 wt % based on a total weight of the polyester base film.

Step c) is a step of manufacturing the film. Here, stretching ratios of the film in the longitudinal and transverse directions are not limited, but may be each 2 to 6 times, and after stretching, relaxing and heat-setting of the stretched film may be further added. More specifically, the film may be manufactured by stretching the un-stretched sheet in the longitudinal and transverse directions and then thermally treating the stretched sheet, wherein the stretching and thermal treating may be performed by a method generally used in the art.

In more detail, although not limited, the stretching in a machine direction may be performed at a stretching ratio of 2 to 6 times between rolls heated to 80 to 90° C. using a difference in speed between the rolls, the stretching in the transverse direction may be performed at a stretching ratio of 2 to 6 times at 100 to 130° C., and the relaxation and thermal treatment may be performed at 210 to 230° C. The polyester base film may have a thickness of 50 to 350 μm, but is not limited thereto.

In step c), a timing point at which a primer coating composition is applied onto the film may be changed depending on a film stretching process. In a sequential biaxial stretching process, the primer coating composition is applied after stretching the film in the longitudinal direction, and then, the film is stretched in the transverse direction. Further, in a simultaneous biaxial stretching process, after the primer coating composition is applied onto an un-stretched sheet, the film may be stretched in the longitudinal and transverse directions.

Step d) is to form the printing layer. In step d), the printing layer may be formed by printing the printing layer composition by a method selected from a screen printing method, an offset method, a digital printing method, a roll coating method, a gravure coating method, a reverse coating method, a spray coating method, and air knife coating method, and a thickness of the printing layer may be 10 to 30 μm, but printing layer is not limited thereto. The printing layer composition is the same as described above.

Hereinafter, the present invention will be described in more detail through Examples and Comparative Examples. However, the following Examples and Comparative Examples are only to specifically explain the present invention, but the present invention is not limited thereto.

Physical properties in the present invention were measured as follows.

1) Intrinsic Viscosity

After dissolving a film in orthochlorophenol (OCP) at 160±2° C., a viscosity of a sample in a viscosity tube was measured using an automatic viscometer (Skyvis-4000) at 25° C., and an intrinsic viscosity(IV) of the sample was calculated according to the following Calculation Equation 1.

$$Intrinsic Viscosity ( IV ) = \{ ( 0.0242 \times Rel ) + 0.2634 \} \times F \\ Rel = \frac{\begin{matrix}seconds of solution \times \\ specific gravity of solution \times \\ viscosity coefficiency\end{matrix}}{OPC viscosity} \\ F = \frac{I . V . of standard chip}{\begin{matrix}average of three I . V . measured \\ from standard chip with standard action\end{matrix} } \qquad [ Calculation Equation 1 ]$$

2) UV Light Transmittance, Visible Light Reflectance, and Visible Light Transmittance

After transmittance at a wavelength of 250 nm to 2500 nm was measured using a UV spectrometer (manufactured by Agilent Technologies, Cary5000 UV-VIS-NIR Spectrophotometer), UV light transmittance was evaluated through average transmittance at a wavelength of 250 nm to 380 nm, visible light transmittance was evaluated through average transmittance at a wavelength of 380 to 1000 nm, and visible light reflectance was evaluated through average reflectance in the same wavelength region. Average transmittance was calculated by adding measurement values at respective wavelengths per nm and calculating an average of the measurement values.

3) Machine Direction (MD) Elongation Retention Rate (%) after Pressure Cooker Test (PCT, at 121° C. and relative humidity (RH) of 100% for 50 hours)

In a length range of 5 m or less in a longitudinal direction of a film roll, a length of sample film is defined as a machine direction (MD) of the film, a width of sample film is defined as a transverse direction (TD) thereof, and two measurement sample films (size: 300 mm×200 mm) were collected. First, after manufacturing a sample (size: 300 mm (MD)x15 mm (TD)) for measuring physical properties using one of the collected measurement sample films, breaking elongation of the film in the machine direction (MD) before PCT treatment was measured 10 times using a tensile test machine (manufactured by Instron Corp.) under the conditions at which the width of the sample to be measured was 15 mm, a gauge length was 50 mm, and a cross head-up speed was 500 mm/min. Then, maximum and minimum values were excluded, and an average value was calculated.

After allowing the sample to have a shape in which cut films (sample size: 200 mm (MD)×15 mm (TD)) were hung on one sample by continuously cutting the other of the collected measurement sample films (size: 300 mm (MD)×200 mm (TD)) 10 times using a cutter at an interval of 15 mm in the transverse direction (TD) based on one edge of the sample so as to have a length of 200 mm in the machine direction (MD), a hole was formed by punching the sample at a position at 270 mm from a cutting start point in the transverse direction (TD) and the sample was hung on a sample hanger in an autoclave to thereby be put into the autoclave so as not to be soaked in water. Then, the sample was aged for 50 hours at high-temperature and high humidity conditions (temperature: 121° C., RH: 100%, pressure: 2 bar). When the aging was completed, the aged sample was picked out from the autoclave and kept at room temperature for 24 hours. Then, a small sample (size: 200 mm (MD)×15 mm (TD)) cut in advance using the cutter before the aging was collected from the sample, and breaking elongation of the film in the machine direction (MD) after PCT treatment was measured 10 times using a tensile test machine (manufactured by Instron Corp.) under the same conditions as described above (that is, the width of the sample to be measured was 15 mm, a gauge length was 50 mm, and a cross head-up speed was 500 mm/min). Then, maximum and minimum values were excluded, and an average value was calculated.

A MD elongation retention rate after PCT was calculated according to the following Calculation Equation 2 using the elongation values in the machine direction before and after PCT treatment.

$$MD elongation retention rate ( \% ) after PCT = \frac{MD elongation after PCT}{MD elongation before PCT} \times 100 \qquad [ Calculation Equation 2 ]$$

4) Thermal Shrinkage Rate

After cutting the film at a size of 200 mm (MD)×200 mm (TD) in a normal direction and measuring lengths of the film in the machine direction (MD) and the transverse direction (TD), the film was thermally shrunk in an oven at 150° C. in a load-free state for 30 minutes. Then, lengths of the thermally shrunk film in the machine direction (MD) and the transverse direction (TD) were measured. Thermal shrinkage rates ΔHS in the machine direction (MD) and the transverse direction (TD) were measured according to the following Calculation Equation 3.

ΔHS=(HS₂−HS₁)/HS₁×100 [Calculation Equation 3]

(In Calculation Equation 3, ΔHS is the thermal shrinkage rate, HS₂ is a length of the polyester base film in a machine direction, measured after standing at 150° C. for 30 minutes, and HS₁ is a length of the polyester base film in the machine direction before treatment.)

5) Evaluation of Adhesion Property

An adhesion property of a formed printing layer was evaluated using a cross cutting test method. Here, as a tape, a glass tape was used, and after the printing layer formed on the sample was cut into 100 pieces (size: 1 lmm×1 mm) in a grid shape, the adhesion property was evaluated by measuring the number of detached pieces after attaching the glass tape to the sample and detaching the glass tape therefrom.

6) Evaluation of Efficiency of Module

After manufacturing modules using the films in Examples according to the present invention and Comparative Examples, efficiency of the modules was compared and evaluated.

A low-iron tempered glass (thickness: 2.5 mm), an ethylene vinyl acetate (EVA) encapsulant (thickness: 500 μm), a single crystal silicon wafer solar cell (6 inches), the EVA encapsulant (thickness: 500 μm), and the film in the Example on which the printing layer was formed or the film in the Comparative Example were sequentially stacked, and compressed in a vacuum state in a vacuum laminator for 5 minutes, followed by pressurization and compression at 150° C. for 10 minutes, thereby manufacturing a solar cell module (expected output power: 200 W).

An open-circuit voltage (V_{oc}), a short-circuit current (I_{sc}), a rated voltage (Vₚₘ), and a rated current (Iₚₘ) of the module were measured using a SPI-SUNSIMULATOR 4600i product (manufactured by Spire Corp.).

In order to evaluate power conversion efficiency of the manufactured module, first, power (Pₘₐₓ) of the module was calculated according to the following Calculation Equation 4, and efficiency of the solar cell module in the Example was compared and evaluated according to the following Calculation Equation 5 based on a power value in Comparative Example 1.

$$\begin{matrix}Power ( W ; {P}_{max} ) of module = Rated voltage ( V ; {V}_{pm} ) \times Rated current ( A ; {I}_{pm} ) & [ Calculation Equation 4 ] \\ efficiency ( \% ) of module = \frac{power ( W ) of module in Example}{\begin{matrix}power ( W ) of module \\ in Comparative Example\end{matrix}} \times 100 & [ Calculation Equation 5 ]\end{matrix}$$

### EXAMPLE 1

1) Preparation of Compound Chip

90 wt % of a polyethylene terephthalate chip having an intrinsic viscosity of 0.95 dl/g and 10 wt % of a benzoxazine-based UV absorber (UV-3638, manufactured by Cytec Corp.) were mixed with each other, kneaded at 30 rpm for 10 minutes in a ribbon mixer, and then, melt-extruded using an intermeshing co-rotating twin-screw extruder having two feed ports and one vent port, thereby preparing a UV blocking compound chip.

2) Manufacturing of Film

5 wt % of a UV blocking compound chip and 85 wt % of a polyethylene terephthalate (PET) chip (intrinsic viscosity: 0.80 dl/g) were put into an extruder and melted at 280° C. Then, while mixture was extruded through a T-die, an un-stretched sheet was manufactured in a casting roll at 20° C. Then, the sheet was stretched 3.5 times in a longitudinal direction, and stretched 3.9 times in a transverse direction, thereby manufacturing a film having a total thickness of 100 μm. A content of a UV stabilizer was 0.5 wt % based on a total weight of the manufactured film.

3) Formation of Printing Layer

30 wt % of titanium oxide fine particles (average particle size: 0.5 μm) coated with 5 wt % of silica as a white pigment and 70 wt % of Golden (Daeyang SPI Co., Ltd.) containing a high content of an acrylic binder resin (solid content: 50 wt %) were mixed with each other, thereby preparing a printing layer composition.

The printing layer composition was applied onto one surface of the polyester base film by a screen printing method, and a printing layer having a thickness of 20 μm was printed at a drying temperature of 80 and a process speed of 1M/min.

Here, the printing layer was formed only on an edge portion of the PET film except for portion of the PET film on which a solar cell will be positioned at the time of assembling a solar cell module as illustrated in FIG. 6.

### 4) Manufacturing of Module

A low-iron tempered glass (thickness: 2.5 mm), an ethylene vinyl acetate (EVA) encapsulant (thickness: 500 μm), a double-sided light receiving single crystal silicon wafer solar cell (6 inches), the EVA encapsulant (thickness: 500 μm), and the backsheet manufactured as described above were stacked, and compressed in a vacuum state for 5 minutes in a vacuum laminator, followed by pressurization and compression at 150° C. for 10 minutes, thereby manufacturing a solar cell module (expected output power: 200 W).

### EXAMPLE 2

A film on which a printing layer having a thickness of 5 μm was printed and a solar cell module were manufactured using 3 wt % of the UV blocking compound chip and the same printing layer composition as in Example 1.

### EXAMPLE 3

A film on which a printing layer having a thickness of 10 μm was printed and a solar cell module were manufactured using 7 wt % of the UV blocking compound chip and the same printing layer composition as in Example 1.

### EXAMPLE 4

A film on which a printing layer having a thickness of 15 μm was printed and a solar cell module were manufactured using 10 wt % of the UV blocking compound chip and the same printing layer composition as in Example 1.

### EXAMPLE 5

A film on which a printing layer having a thickness of 25 μm was printed and a solar cell module were manufactured using 5 wt % of the UV blocking compound chip and the same printing layer composition as in Example 1.

### COMPARATIVE EXAMPLE 1

A film and a solar cell module were manufactured by the same method as in Example 1 except that the UV blocking compound chip was not used, only a polyethylene terephthalate chip having an intrinsic viscosity of 0.68 dl/g was used, and a printing layer was not formed.

### COMPARATIVE EXAMPLE 2

A film and a solar cell module were manufactured by the same method as in Example 1 except that 10 wt % of the UV blocking compound chip was used, and a printing layer was not formed.

### COMPARATIVE EXAMPLE 3

After a film was manufactured using only a polyethylene terephthalate chip having an intrinsic viscosity of 0.62 dl/g by the same method as in Example 1 without using the UV blocking compound chip, a film on which a printing layer was formed and a solar cell module were manufactured by the same method as in Example 1.

### COMPARATIVE EXAMPLE 4

A film on which a printing layer was formed and a solar cell module were manufactured using 10 wt % of the UV blocking compound chip and a mixture in which 10 wt % of tetrafluoroethylene (TFE) was added to the same printing layer composition as in Example 1.

TABLE 1

| | Physical properties of Polyester base film in Manufactured Module | | | | | | |
|---|---|---|---|---|---|---|---|
| | Intrinsic | | | | Average | Average | |
| | viscosity | | Thermal | | UV Light | Visible Light | UV Light |
| | (dl/g) of | Content | Shrinkage | Elongation | Transmittance | Transmittance | Transmittance |
| | Polyester | (wt %) of | Rate (%) | Retention | (%) at 250 | (%) at 380 | (%) at |
| Classification | base film | Photostabilizer | (MD/TD) | Rate (%) | to 380 nm | to 1000 nm | 550 nm |
| Example1 | 0.72 | 0.5 | 1.2/1.0 | 61 | 2.1 | 91 | 89 |
| Example2 | 0.72 | 0.3 | 1.2/1.0 | 61 | 8.2 | 91 | 89 |
| Example3 | 0.71 | 0.7 | 1.2/1.0 | 59 | 2.0 | 91 | 89 |
| Example4 | 0.71 | 1.0 | 1.2/1.0 | 60 | 1.5 | 92 | 89 |
| Example5 | 0.72 | 0.5 | 1.2/1.0 | 61 | 2.1 | 91 | 89 |
| Comparative | 0.64 | 0 | 1.1/1.0 | 42 | 86 | 91 | 89 |
| Example1 | | | | | | | |
| Comparative | 0.72 | 1.0 | 1.2/1.0 | 38 | 1.5 | 92 | 89 |
| Example2 | | | | | | | |
| Comparative | 0.61 | 0 | 1.3/1.0 | 34 | 86 | 91 | 89 |
| Example3 | | | | | | | |
| Comparative | 0.72 | 1.0 | 1.2/1.0 | 32 | 1.7 | 82 | 77 |
| Example4 | | | | | | | |

TABLE 2

| | Physical Properties of Printing | | | | | |
|---|---|---|---|---|---|---|
| | Layer in Manufactured Module | | | Physical Properties of Module | | |
| | Thickness | Visible Light | Visible Light | Adhesion Property | | |
| | (μm) of | Reflectance | Reflectance | between Base Film | Power (Pmax) | Efficiency |
| | Printing | (%) at 380 | (%) at | and Printing | of Solar cell | (%) of |
| Classification | Layer | to 1000 nm | 550 nm | Layer (ea) | module | Module |
| Example1 | 20 | 91 | 91 | 0 | 211 | 105 |
| Example2 | 5 | 85 | 86 | 0 | 203 | 101 |
| Example3 | 10 | 87 | 87 | 0 | 206 | 102 |
| Example4 | 15 | 89 | 89 | 0 | 208 | 104 |
| Example5 | 25 | 92 | 92 | 0 | 212 | 106 |
| Comparative | 0 | 42 | 45 | — | 201 | 100 |
| Example1 | | | | | | |
| Comparative | 0 | 39 | 45 | — | 200 | 99.5 |
| Example2 | | | | | | |
| Comparative | 20 | 87 | 86 | 0 | 210 | 104.5 |
| Example3 | | | | | | |
| Comparative | 20 | 79 | 80 | 17 | 211 | 105 |
| Example4 | | | | | | |

As illustrated in Tables 1 and 2, it may be appreciated that since in each of the backsheets for a solar cell module in Examples 1 to 5 according to the present invention, a portion on which the solar cell was positioned was transparent, the backsheets may be applied to a double-sided light receiving Solar cell module; and average visible light transmittance at a wavelength of 380 to 1000 nm was 85% or more, visible light transmittance at a wavelength of 550 nm was 85% or more, average UV light transmittance at a wavelength of 250 to 380 nm was 10% or less, and at the same time, average visible light reflectance of the printing layer at a wavelength of 380 to 1000 nm was 85% or more, and visible light reflectance of the printing layer at a wavelength of 550 nm was 85% or more, such that the physical properties were excellent. It may be appreciated that in Example 1, at the time of manufacturing the solar cell module, maximum output power was 212 W, such that the output power thereof also was excellent, and at the time of applying the backsheet to the double-sided light receiving solar cell module, light receiving efficiency may be improved by at most 6% or more.

1. A backsheet for a solar cell module comprising:
a polyester base film; and
a printing layer formed on only a portion of one surface or both surfaces of the polyester base film,
wherein the printing layer contains a white pigment.

2. The backsheet for a solar cell module of claim 1, wherein average visible light transmittance of the polyester base film at a wavelength of 380 to 1000 nm is 85% or more, and average UV light transmittance thereof at a wavelength of 250 to 380 nm is 10% or less.

3. The backsheet for a solar cell module of claim 1, wherein average visible light reflectance of the printing layer at a wavelength of 380 to 1000 nm is 85% or more.

4. The backsheet for a solar cell module of claim 1, wherein the polyester base film contains any one or two or more photostabilizers selected from the group consisting of a benzophenone based compound, a benzotriazole based compound, a benzoxazinone based compound, a benzoate based compound, a phenyl salicylate based compound, and a hindered amine based compound.

5. The backsheet for a solar cell module of claim 4, wherein a content of the photostabilizer is 0.01 to 5 wt % based on a total weight of the polyester base film.

6. The backsheet for a solar cell module of claim 1, wherein an intrinsic viscosity of the polyester base film is 0.65 to 0.8 dl/g, a thermal shrinkage rate ΔHS thereof after standing at 150° C. for 30 minutes satisfies the following Equation 1, and an elongation retention rate S thereof after standing at 121° C. and RH of 100% for 75 hours satisfies the following Equation 2:
0≤ΔHS≤2 [Equation 1]
in Equation 1, ΔHS=(HS₂−HS₁)/HS₁×100, wherein ΔHS is the thermal shrinkage rate, HS₂ is a length of a polyester base film in a machine direction, measured after standing at 150° C. for 30 minutes, and HS₁ is a length of the polyester base film in the machine direction before treatment, and
60%≤S≤99% [Equation 2]
in Equation 2, S=S₂/S₁×100, wherein S is the elongation retention rate in the machine direction, S₂ is an elongation of the polyester base film in the machine direction, measured after standing at 121° C. and RH of 100% for 75 hours, and S₁ is an elongation thereof in the machine direction (MD) of the polyester base film before treatment.

7. The backsheet for a solar cell module of claim 1, wherein the polyester base film has a thickness of 50 to 350 μm, and the printing layer has a thickness of 1 to 35 μm.

8. The backsheet for a solar cell module of claim 1, wherein the printing layer contains an acrylic based resin, a polyester based resin, or a polyurethane based resin as a binder resin.

9. The backsheet for a solar cell module of claim 1, wherein the white pigment is contained in the printing layer in a content of 30 to 50 wt %.

10. The backsheet for a solar cell module of claim 9, wherein the white pigment is made of titanium oxide fine particles coated with silica and having an average particle size of 0.15 to 0.25 μm.

11. The backsheet for a solar cell module of claim 1, wherein the printing layer is selected from i) printing layers formed only on a portion of a surface of the polyester base film to be disposed apart from each other, ii) a printing layer formed only on a portion of the surface of the polyester base film and having a continuous pattern, iii) a printing layer formed only on a portion of the surface of the polyester base film along an edge of a solar cell, and iv) a printing layer formed only on a portion of the surface of the polyester base film in a sea island form.

12. The backsheet for a solar cell module of claim 1, wherein the printing layer partially overlaps a solar cell of the solar cell module.

13. The backsheet for a solar cell module of claim 1, wherein the polyester base film is composed of a polyester film and a primer coating layer containing any one of a polyurethane based resin and a polyester based resin or a mixture thereof and formed on one surface or both surfaces of the polyester film.

14. A manufacturing method of a backsheet for a solar cell module, the manufacturing method comprising:
a) preparing a compound chip by kneading a polyester resin having an intrinsic viscosity of 0.8 to 1.0 dl/g and a photostabilizer;
b) manufacturing an un-stretched sheet by adding the compound chip to a polyester resin having an intrinsic viscosity of 0.65 to 0.8 dl/g and melt-extruding the resultant, the compound chip being added in a content range in which the following physical properties are satisfied:
average visible light transmittance at a wavelength of 380 to 1000 nm is 85% or more, and average UV light transmittance at a wavelength of 250 to 380 nm is 10% or less;
c) manufacturing a polyester base film by uni-axially stretching the un-stretched sheet in a longitudinal direction and then bi-axially stretching the sheet in a transverse direction; and
d) forming a printing layer by applying a printing layer composition containing a binder resin, an organic solvent, and a white pigment onto only a portion of a surface of a polyester base film, the white pigment being contained in a content range in which the printing layer satisfies the following physical property: average visible light reflectance at a wavelength of 380 to 1000 nm is 85% or more.

15. The manufacturing method of claim 14, wherein in step d), an application method is selected from a screen printing method, an offset method, a digital printing method, a roll coating method, a gravure coating method, a reverse coating method, a spray coating method, and an air knife coating method.
